(19) United States
(12) Patent Application Publication
(10) Pub. No.: US 2012/0256213 A1
(43) Pub. Date: Oct. 11, 2012

(54) LED STRUCTURE AND MANUFACTURING METHOD THEREOF

(75) Inventors: Kuangyao Chang, Shenzhen (CN); Chechang Hu, Shenzhen (CN); Jing Zhang, Shenzhen (CN)

(73) Assignee: SHENZHEN CHINA STAR OPTOELECTONICS TECHNOLOGY CO., LTD., Shenzhen, Guangdong (CN)

(21) Appl. No.: 13/128,102

(22) PCT Filed: Apr. 14, 2011
(86) PCT No.: PCT/CN11/72813

§ 371 Date: May 6, 2011

(30) Foreign Application Priority Data
Apr. 8, 2011 (CN) 201110087917.6

(51) Int. Cl. H01L 33/50; H01L 33/48

(52) U.S. Cl. 257/98; 438/27; 438/26; 257/100; 257/E33.06; 257/E33.059

(57) ABSTRACT

The present invention discloses an LED structure and a manufacturing method thereof. The LED structure has a housing, an LED chip and a transparent encapsulant. The housing has a recess and at least one protruded wall. The LED chip is received in the recess. The transparent encapsulant is formed by dispensing a molding compound into the recess by an adhesive dispenser. The transparent encapsulant has an edge matched with an edge of the recess to encapsulate the LED chip in the recess, and has a height smaller than that of the protruded wall. The LED chip of the LED structure of the present invention can emit light through the spherical surface of the transparent encapsulant based on a greater visual angle, and thus enhance the light extraction efficiency.

### FIELD OF THE INVENTION

The present invention relates to an LED (light emitting diode) structure and a manufacturing method thereof, and more particularly to an LED structure having a transparent encapsulant with a spherical surface and a manufacturing method thereof.

### BACKGROUND OF THE INVENTION

A liquid crystal display (LCD) is a type of flat panel display (FPD), which shows images by the property of liquid crystal material. Comparing with other display devices, the liquid crystal display has advantages in lightweight, compactness, low driving voltage and low power consumption, and thus has already become the mainstream product in the whole consumer market. However, the liquid crystal material of the liquid crystal display cannot emit light by itself, and must depend upon an external light source. Thus, the liquid crystal display further has a backlight module to provide the needed light source.

Generally, the backlight module can be divided into two types, i.e. the side-light type backlight module and the direct-light type backlight module. Traditional backlight modules mainly use cold cathode fluorescent lamps (CCFLs), hot cathode fluorescent lamps (HCFLs) or semiconductor emitting diodes as light sources, wherein the semiconductor emitting diodes mainly use light emitting diodes (LEDs) to emit light. In comparison with the cathode fluorescent lamps, the light emitting diodes can save more electric power, have longer lifetime, and more compact volume, so that there is a trend to gradually use the light emitting diodes to replace the cathode fluorescent lamps.

Nowadays, an LED is generally in form of chip to be assembled into a semiconductor package, i.e. an LED package structure, which is finally connected to a fixed plate of a backlight module. Product types of the LED package structures are classified according to condition features including light colors, chip material, luminance, size and etc. A single chip generally can construct a point type light source, while a plurality of assembled chips can construct a surface type light source or a linear type light source for the purpose of signaling, indicating status, or displaying. The light emitting display is constructed by a plurality of chips suitably connected (in series or in parallel) and suitable optical structures, all of which construct light emitting sections and light emitting points of the light emitting display. Furthermore, a surface-mounting-device type LED (SMD-LED) is attached to a surface of a circuit board, so that it is suitably applied to a SMT (surface mounting technology) process for carrying out reflowing. Thus, it can efficiently solve problems of brightness, visual angle, evenness, reliability, uniformity and etc. Moreover, the SMD-LED is used with lighter material of a PCB board and a reflective layer, and omitted terminals made of carbon steel in a dip type LED, so that epoxy resin filled in a display reflective layer can be reduced, and a half of product weight of the SMD-LED can be easily removed to finally optimize the application thereof. Thus, the SMD-LED gradually replaces the terminal type LED, and can provide more flexible designs, especially occupying a market share in the LED display market and having a trend of rapidly developing.

Referring now to FIG. 1, a cross-sectional view of a traditional LED structure is illustrated. The LED structure 90 comprises a housing 91, a first electrode plate 92, a second electrode plate 93, an LED chip 94 and a transparent encapsulant 95. An upper surface of the housing 91 is formed with a recess 911. A portion of the first electrode plate 92 is disposed on the bottom of the recess 911, and the other portion thereof is extended out of the housing 91 for being electrically connected with an external power supply. A portion of the second electrode plate 93 is disposed on the bottom of the recess 911, and the other portion thereof is extended out of the housing 91 for being electrically connected with an external power supply. The LED chip 94 has a first electrode (not-shown) and a second electrode (not-shown). The LED chip 94 is disposed in the recess 911, wherein the first electrode is electrically connected with the first electrode plate 92, and the second electrode is electrically connected with the second electrode plate 93 through a first wire 96. The transparent encapsulant 95 encapsulates the recess 911 and encapsulates the components in the recess 911, wherein the light of the LED 94 can emit upward through the transparent encapsulant 95.

In the traditional LED structure 90, the design of the housing 91 should have an ideal transparent encapsulant 95 with a horizontal surface. However, due to the shrinkage of the material of the transparent encapsulant 95 after hardening and the surface tension action on the surface of the transparent encapsulant 95 enclosed by the edge of the recess 911 of the housing 91, a central portion of the surface of the transparent encapsulant 95 is actually in a recessed status. Because the refractive index of the transparent encapsulant 95 is greater than that of the air, a portion of light will be total reflected, when the light passes through an interface between the surface of the transparent encapsulant 95 and the air. Even though the light of total reflection is reflected from walls of the recess 911 and then emits out of the transparent encapsulant 95, the light still will be attenuated to affect the light extraction efficiency.

Referring now to FIG. 2, a cross-sectional view of another traditional LED structure is illustrated. As shown in FIG. 2, the LED structure 90′ of FIG. 2 is substantially the same as the LED structure 90 of FIG. 1, and comprises a housing 91′, a recess 911′, a first electrode plate 92′, a second electrode plate 93′, an LED chip 94′, a transparent encapsulant 95′ and a wire 96′. The difference between the two traditional LED structures 90 and 90′ is that: the transparent encapsulant 95′ of the LED structure 90′ of FIG. 2 has a design of a spherical surface. Thus, it can prevent from the attenuation condition due to the total reflection of the light, as described above, while the light can be efficiently emitted outward with a greater visual angle. However, when manufacturing the LED structure 90′, it needs to firstly use a molding compound to fill a space 952′ in the transparent encapsulant 95′, and then form a protruded external portion 952′ of the transparent encapsulant 95′ by plastic injection molding (or then install with a pre-fabricated external portion 952′). Thus, it will relatively increase the manufacture cost of the transparent encapsulant 95′. Meanwhile, because the transparent encapsulant 95′ is protruded from the housing 91′, it is easy to damage the transparent encapsulant 95′, and it is disadvantageous to execute the following SMT or other manufacturing processes of the LED structure 90′.

As a result, it is necessary to provide an LED structure and a manufacturing method thereof to solve the problems existing in the conventional technologies, as described above.

### SUMMARY OF THE INVENTION

A first object of the present invention is to provide an LED structure, which can emit light with a greater visual angle and enhance the light extraction efficiency.

A second object of the present invention is to provide a manufacturing method of an LED structure, which can emit light with a greater visual angle and enhance the light extraction efficiency.

To achieve the above object, the present invention provides an LED structure which comprises:

a housing having a recess and at least one protruded wall which is formed on a periphery of the recess;

an LED chip disposed in the recess of the housing; and

a transparent encapsulant encapsulating the recess of the housing, wherein the transparent encapsulant has an edge matched with an edge of the recess to encapsulate the LED chip in the recess and has a spherical surface with a height smaller than that of the protruded wall; and wherein the LED chip is disposed at a spherical central position of the spherical surface of the transparent encapsulant or a position close to the spherical central position.

In one embodiment of the present invention, the protruded wall is formed on two opposite sides of the recess or surrounding around the recess to enclose the recess.

In one embodiment of the present invention, material of the transparent encapsulant is silicone resin or silicone resin mixed with phosphor.

To achieve the above object, the present invention further provides an LED structure, which comprises:

a housing having a recess and at least one protruded wall which is formed on a periphery of the recess;

an LED chip disposed in the recess of the housing; and

a transparent encapsulant encapsulating the recess of the housing, wherein the transparent encapsulant has an edge matched with an edge of the recess to encapsulate the LED chip in the recess and has a spherical surface with a height smaller than that of the protruded wall.

In one embodiment of the present invention, the LED chip is disposed at a central position in the recess of the housing, and a highest point of the spherical surface of transparent encapsulant is located over a center of the LED chip.

In one embodiment of the present invention, the LED chip is disposed at a spherical central position of the spherical surface of the transparent encapsulant or a position close to the spherical central position.

In one embodiment of the present invention, the protruded wall is formed on two opposite sides of the recess or surrounding around the recess to enclose the recess.

In one embodiment of the present invention, material of the transparent encapsulant is silicone resin or silicone resin mixed with phosphor.

To achieve the above object, the present invention further provides a manufacturing method of an LED structure, which comprises the following steps of:

preparing a housing having a recess and at least one protruded wall, wherein the recess has an LED chip therein and the protruded wall is formed on a periphery of the recess;

preparing an adhesive dispenser loaded with a molding compound and placed above the recess; and

dispensing the molding compound into the recess by the adhesive dispenser to form a transparent encapsulant, wherein the transparent encapsulant has an edge matched with an edge of the recess to encapsulate the LED chip in the recess and has a spherical surface with a height smaller than that of the protruded wall.

In one embodiment of the present invention, the LED chip is disposed at a central position in the recess of the housing, and the adhesive dispenser is located over a center of the LED chip.

In one embodiment of the present invention, the volume of the molding compound dispensed by the adhesive dispenser is greater than that of the recess of the housing.

In one embodiment of the present invention, the LED chip is disposed at a spherical central position of the spherical surface of the transparent encapsulant or a position close to the spherical central position.

In one embodiment of the present invention, the protruded wall is formed on two opposite sides of the recess or surrounding around the recess to enclose the recess.

In one embodiment of the present invention, material of the molding compound is silicone resin or silicone resin mixed with phosphor.

The present invention provides an LED structure and a manufacturing method thereof. The LED structure has a housing, an LED chip and a transparent encapsulant. The housing has a recess and at least one protruded wall; the LED chip is received in the recess. The transparent encapsulant is formed by dispensing a molding compound into the recess by an adhesive dispenser, while the transparent encapsulant has an edge matched with an edge of the recess to encapsulate the LED chip in the recess and has a spherical surface with a height smaller than that of the protruded wall. The LED chip of the LED structure of the present invention can emit light through the spherical surface of the transparent encapsulant based on a greater visual angle, and thus enhance the light extraction efficiency. Furthermore, because the height of the protruded wall is greater than that of the transparent encapsulant, it is advantageous to execute the following SMT or other manufacturing processes of the LED structure and to provide a function of protecting the transparent encapsulant of the LED structure from being damaged during the following manufacturing processes.

### DESCRIPTION OF THE DRAWINGS

FIG. 1 is a cross-sectional view of a traditional LED structure;

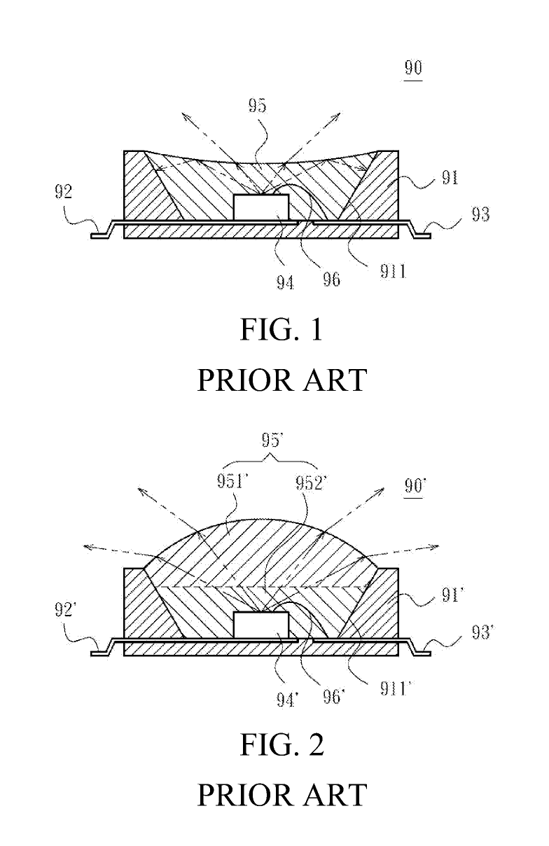

FIG. 2 is a cross-sectional view of another traditional LED structure;

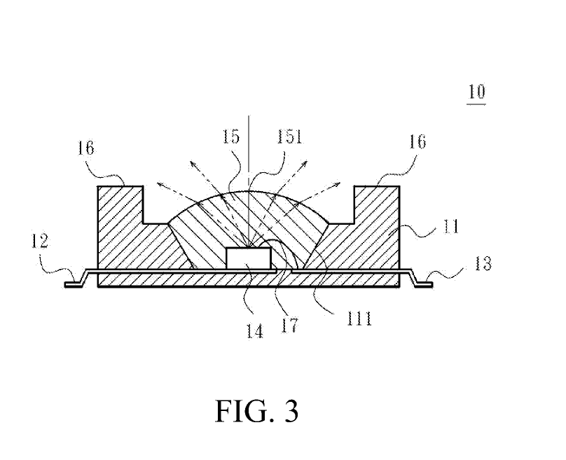

FIG. 3 is a cross-sectional view of an LED structure according to a first embodiment of the present invention;

FIG. 4 is a flowchart of a manufacturing method of the LED structure according to the first embodiment of the present invention;

FIGS. 5A to 5D are schematic views of the flowchart of the manufacturing method of the LED structure according to the first embodiment of the present invention; and

FIG. 6 is a cross-sectional view of an LED structure according to a second embodiment of the present invention.

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings.

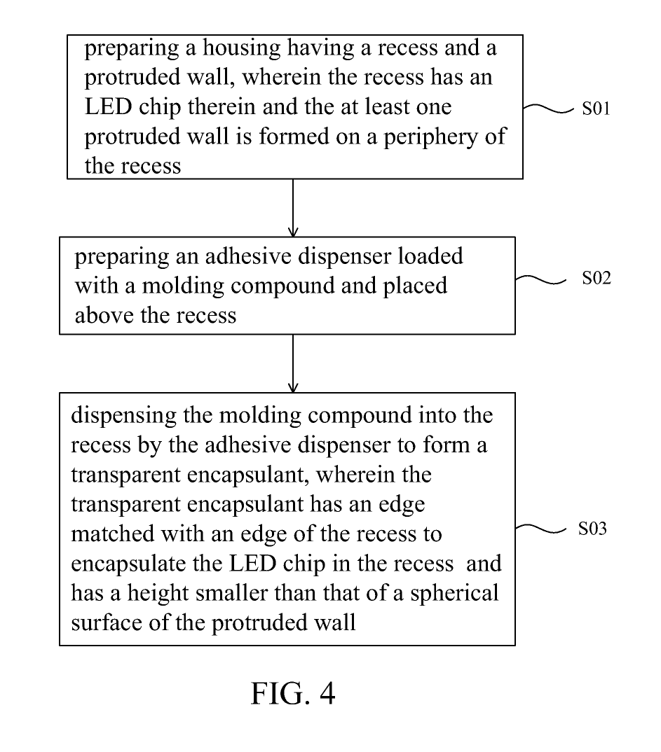

Referring now to FIG. 3, a cross-sectional view of an LED (light emitting diode) structure according to a first embodiment of the present invention is illustrated. The LED structure 10 comprises: a housing 11, a first electrode plate 12, a second electrode plate 13, a LED chip 14 and a transparent encapsulant 15. The housing 11 has a recess 111 which is a concave structure and has a shape capable of being adjusted corresponding to product needs. A periphery of the housing 11 is formed with two protruded walls 16, and the protruded walls 16 are formed on two opposite sides of the recess 111.

A portion of the first electrode plate 12 is disposed in the recess 111, and the other portion thereof is extended out of the housing 11 for being electrically connected with an external power supply. A portion of the second electrode plate 13 is disposed in the recess 111, and the other portion thereof is extended out of the housing 11 for being electrically connected with an external power supply. The LED chip 14 has a first electrode (not-shown) and a second electrode (not-shown). The LED chip 14 is disposed in the recess 111, wherein the LED chip 14 is disposed at a central position in the recess 111. The first electrode of the LED chip 14 is electrically connected with the first electrode plate 12, and the second electrode thereof is electrically connected with the second electrode plate 13 through a first wire 17.

The transparent encapsulant 15 encapsulates the recess 111 of the housing 11 by an adhesive dispensing process, so as to encapsulate the LED chip 14, a portion of the first electrode plate 12 and a portion of the second electrode plate 13 in the recess 111. Furthermore, by controlling the dispensing amount of adhesive in the adhesive dispensing process and using the surface tension action on the surface of the transparent encapsulant 15, an edge of the transparent encapsulant 15 can be matched with an edge of the recess 111 to form a spherical surface, wherein a height of the transparent encapsulant 15, i.e. a height of a highest point 151 of the spherical surface, is greater than the height of the edge of the recess 111, and smaller than the height of the protruded wall 16.

Referring to FIG. 3, the LED chip 14 is preferably disposed at the central position in the recess 111 of the housing 11, and the highest point 151 of the spherical surface of the transparent encapsulant 15 is located over a center of the LED chip 14. Thus, the LED chip 14 of the LED structure 10 of the present invention can emit light through the spherical surface of the transparent encapsulant 15 based on a greater visual angle, and thus enhance the light extraction efficiency.

In addition, material of the transparent encapsulant is preferably silicone resin or silicone resin mixed with phosphor, wherein the silicone resin has better encapsulating property and light transmittance, and the silicone resin added with the phosphor can enhance the entire light extraction efficiency.

Moreover, because the height of the protruded wall 16 is greater than that of the transparent encapsulant 15, it is advantageous to execute the following SMT or other manufacturing processes of the LED structure 10 and to provide a function of protecting the transparent encapsulant 15 of the LED structure 10 from being damaged during the following manufacturing processes. However, although the number of the protruded wall 16 in the first embodiment of the present invention is two, the number and shape of the protruded wall 16 of the present invention are not limited thereto. The protruded wall 16 also can be surrounding around the recess 111 to enclose the recess 111. A user can adjust the number and shape of the protruded wall 16 according to actual needs, so as to satisfy needs of suction needs during manufacturing processes and to carry out the purpose of protecting the transparent encapsulant 15.

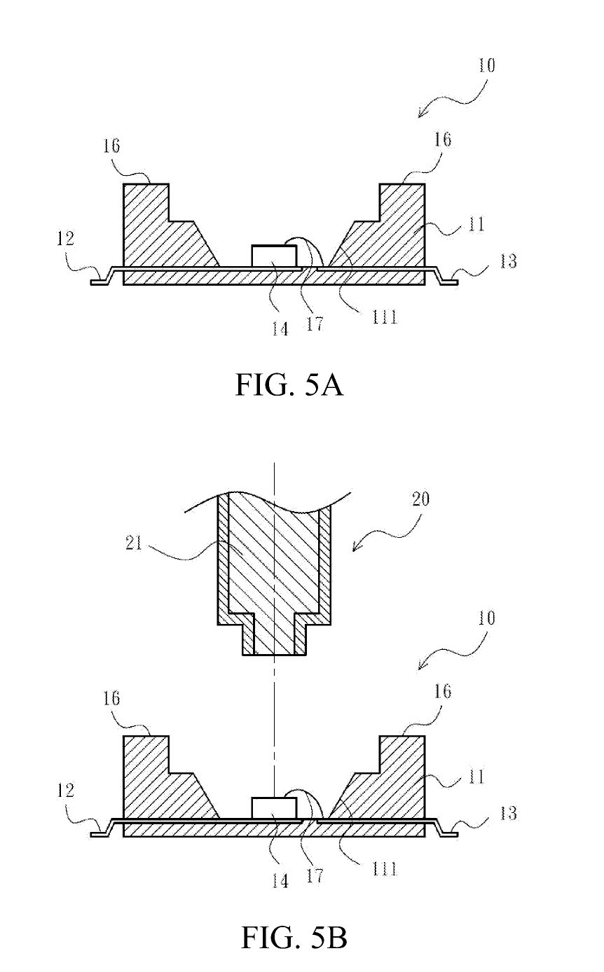

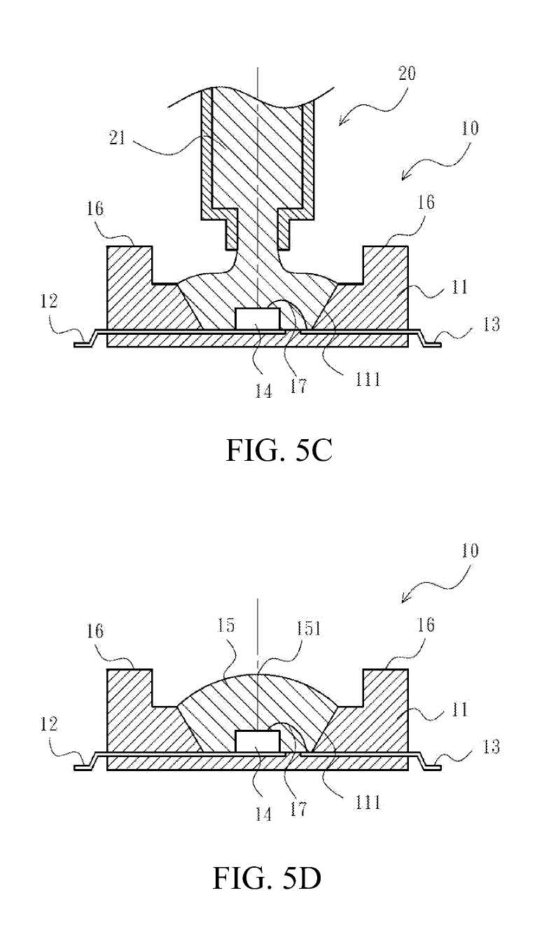

Referring now to FIG. 4 and FIGS. 5A to 5D, in the preferred embodiment of the present invention, FIG. 4 is a flowchart of a manufacturing method of the LED structure according to the first embodiment of the present invention; and FIGS. 5A to 5D are schematic views of the flowchart of the manufacturing method of the LED structure according to the first embodiment of the present invention.

In a step (S01), preparing a housing 11 having a recess 111 and at least one protruded wall 16, wherein the recess 111 of the housing 11 has an LED chip 14 therein and the protruded wall 16 is formed on a periphery of the recess 11, i.e. the protruded wall 16 is formed on two opposite sides of the recess 111 or surrounding around the recess 111 to enclose the recess 111;

In a step (S02), preparing an adhesive dispenser 20 which is loaded with a molding compound 21 and placed above the recess 111; and

In a step (S03), dispensing the molding compound 21 with a suitable volume into the recess 111 by the adhesive dispenser 20 to form a transparent encapsulant 15, wherein the adhesive dispenser 20 precisely controls the output volume of the molding compound 21, so that the volume of the molding compound 21 injected by the adhesive dispenser is greater than that of the recess 111 of the housing 11. Furthermore, by using the surface tension action on the surface of the transparent encapsulant 15, the edge of the transparent encapsulant 15 formed by coagulating the molding compound 21 is matched with the edge of the recess 111, so as to encapsulate the LED chip 14, a portion of the first electrode plate 12 and a portion of the second electrode plate 13 in the recess 111, wherein the transparent encapsulant 15 has a spherical surface with a height smaller than that of the protruded wall 16.

Preferably, the LED chip 14 is disposed at a central position in the recess 111 of the housing 11, and the adhesive dispenser 20 is located over a center of the LED chip 14. Besides, material of the molding compound 21 is silicone resin or silicone resin mixed with phosphor.

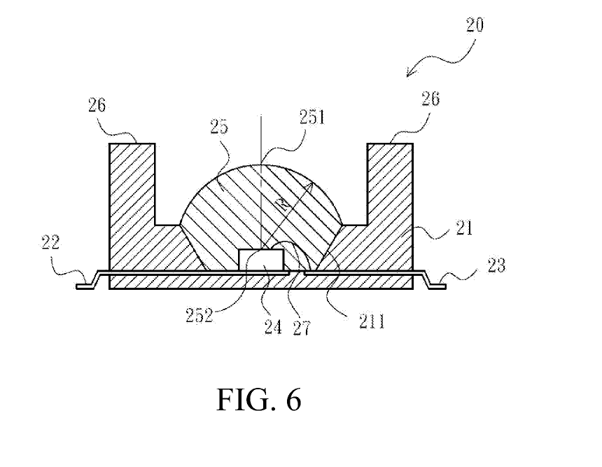

Referring now to FIG. 6, a cross-sectional view of an LED structure according to a second embodiment of the present invention is illustrated, and the LED structure 20 of the embodiment is similar to the LED structure 10 of the first embodiment, so that the second embodiment uses the same terms of the first embodiment. The LED structure 20 of the embodiment comprises: a housing 21, a recess 211, a first electrode plate 22, a second electrode plate 23, a LED chip 24, a transparent encapsulant 25, at least one protruded wall 26 and a wire 27, but the difference between the two embodiment is that: a highest point 251 of the spherical surface formed by the transparent encapsulant 25 is higher than the highest point 151 of the spherical surface of the first embodiment, wherein the highest point 251 of the transparent encapsulant 25 is disposed over a center of the LED chip 24, while the LED chip 24 is disposed at a spherical central position 252 of the spherical surface of the transparent encapsulant 25 or a position close to the spherical central position 252. In this case, the radius of the spherical surface of the transparent encapsulant 25 is “R”. Thus, the LED chip 24 is disposed at the spherical central position 252 of the spherical surface of the transparent encapsulant 25, in order to further enhance the entire light extraction efficiency.

As described above, according to the LED structure and a manufacturing method thereof in the present invention, the transparent encapsulant is formed by dispensing a molding compound into the recess of the housing of the LED structure by an adhesive dispenser, while the transparent encapsulant has an edge matched with an edge of the recess to encapsulate the LED chip in the recess and is formed with a spherical surface. The LED chip of the LED structure of the present invention can emit light through the spherical surface of the transparent encapsulant based on a greater visual angle, and thus enhance the light extraction efficiency.

The present invention has been described with a preferred embodiment thereof and it is understood that many changes and modifications to the described embodiment can be carried out without departing from the scope and the spirit of the invention that is intended to be limited only by the appended claims.

1. An LED structure, characterized in that: the LED structure comprises:
a housing having a recess and at least one protruded wall which is formed on a periphery of the recess;
an LED chip disposed in the recess of the housing; and
a transparent encapsulant encapsulating the recess of the housing, wherein the transparent encapsulant has an edge matched with an edge of the recess to encapsulate the LED chip in the recess and has a spherical surface with a height smaller than that of the protruded wall; and wherein the LED chip is disposed at a spherical central position of the spherical surface of the transparent encapsulant or a position close to the spherical central position.

2. The LED structure according to claim 1, characterized in that: the protruded wall is formed on two opposite sides of the recess or surrounding around the recess to enclose the recess.

3. The LED structure according to claim 1, characterized in that: material of the transparent encapsulant is silicone resin or silicone resin mixed with phosphor.

4. An LED structure, characterized in that: the LED structure comprises:
a housing having a recess and at least one protruded wall which is formed on a periphery of the recess;
an LED chip disposed in the recess of the housing; and
a transparent encapsulant encapsulating the recess of the housing, wherein the transparent encapsulant has an edge matched with an edge of the recess to encapsulate the LED chip in the recess and has a spherical surface with a height smaller than that of the protruded wall.

5. The LED structure according to claim 4, characterized in that: the LED chip is disposed at a central position in the recess of the housing, and a highest point of the spherical surface of transparent encapsulant is located over a center of the LED chip.

6. The LED structure according to claim 5, characterized in that: the LED chip is disposed at a spherical central position of the spherical surface of the transparent encapsulant or a position close to the spherical central position.

7. The LED structure according to claim 4, characterized in that: the protruded wall is formed on two opposite sides of the recess or surrounding around the recess to enclose the recess.

8. The LED structure according to claim 4, characterized in that: material of the transparent encapsulant is silicone resin or silicone resin mixed with phosphor.

9. A manufacturing method of an LED structure, characterized in that: the manufacturing method of the LED structure comprises steps of:
preparing a housing having a recess and at least one protruded wall, wherein the recess has an LED chip therein and the protruded wall is formed on a periphery of the recess;
preparing an adhesive dispenser loaded with a molding compound and placed above the recess; and
dispensing the molding compound into the recess by the adhesive dispenser to form a transparent encapsulant, wherein the transparent encapsulant has an edge matched with an edge of the recess to encapsulate the LED chip in the recess and has a spherical surface with a height smaller than that of the protruded wall.

10. The manufacturing method of the LED structure according to claim 9, characterized in that: the LED chip is disposed at a central position in the recess of the housing, and the adhesive dispenser is located over a center of the LED chip.

11. The manufacturing method of the LED structure according to claim 9, characterized in that: the volume of the molding compound of the adhesive dispenser is greater than that of the recess of the housing.

12. The manufacturing method of the LED structure according to claim 9, characterized in that: the LED chip is disposed at a spherical central position of the spherical surface of the transparent encapsulant or a position close to the spherical central position.

13. The manufacturing method of the LED structure according to claim 9, characterized in that: the protruded wall is formed on two opposite sides of the recess or surrounding around the recess to enclose the recess.

14. The manufacturing method of the LED structure according to claim 9, characterized in that: material of the molding compound is silicone resin or silicone resin mixed with phosphor.
